(19) United States
(12) Patent Application Publication
(10) Pub. No.: US 2017/0077020 A1
(43) Pub. Date: Mar. 16, 2017

(54) SEMICONDUCTOR DEVICE

(71) Applicant: Kabushiki Kaisha Toshiba, Minato-ku (JP)

(72) Inventors: Hide MABUCHI, Kamakura (JP); Keiji HAMODA, Yokohama (JP); Kazumichi HADA, Kawasaki (JP)

(73) Assignee: Kabushiki Kaisha Toshiba, Minato-ku (JP)

(21) Appl. No.: 14/978,029

(22) Filed: Dec. 22, 2015

Related U.S. Application Data
(60) Provisional application No. 62/216,759, filed on Sep. 10, 2015.

(51) Int. Cl. H01L 23/498; H01L 23/31

(52) U.S. Cl. CPC H01L 23/49838; H01L 23/3114

(57) ABSTRACT

According to one embodiment, there is provided a semiconductor device including a package. The package includes a first terminal, a second terminal, a semiconductor chip, and a sealing member. The first terminal is compatible with a first bus standard. The second terminal is compatible with a second bus standard. In the semiconductor chip, the first terminal and the second terminal are electrically connected. The sealing member covers one end of the first terminal and one end of the second terminal, exposes an other end of the first terminal and an other end of the second terminal, and covers the semiconductor chip.

### CROSS-REFERENCE TO RELATED APPLICATIONS

This application is based upon and claims the benefit of priority from U.S. Provisional Application No. 62/216,759, filed on Sep. 10, 2015 the entire content of which are incorporated herein by reference.

### FIELD

Embodiments described herein relate generally to a semiconductor device.

### BACKGROUND

In a semiconductor device, a semiconductor chip may be housed in a package. At this time, it is desired to improve convenience of the semiconductor device.

### BRIEF DESCRIPTION OF THE DRAWINGS

FIGS. 1A to 1C are a plan view and cross-sectional views illustrating a configuration of a semiconductor device according to an embodiment;

FIG. 2 is a perspective view illustrating a configuration of a package according to the embodiment;

FIG. 3 is a perspective view illustrating a configuration of the package, which is before being sealed by resin, according to the embodiment;

FIG. 4 is a circuit diagram illustrating a configuration of the package according to the embodiment;

FIGS. 5A and 5B are a plan view and a cross-sectional view illustrating a configuration of a semiconductor device according to a modified example of the embodiment;

FIGS. 6A and 6B are a plan view and a cross-sectional view illustrating a configuration of a semiconductor device according to another modified example of the embodiment;

FIGS. 7A and 7B are a plan view and a cross-sectional view illustrating a configuration of a semiconductor device according to another modified example of the embodiment; and

FIGS. 8A to 8C are a plan view and cross-sectional views illustrating a configuration of a semiconductor device according to another modified example of the embodiment.

### DETAILED DESCRIPTION

In general, according to one embodiment, there is provided a semiconductor device including a package. The package includes a first terminal, a second terminal, a semiconductor chip, and a sealing member. The first terminal is compatible with a first bus standard. The second terminal is compatible with a second bus standard. In the semiconductor chip, the first terminal and the second terminal are electrically connected. The sealing member covers one end of the first terminal and one end of the second terminal, exposes an other end of the first terminal and an other end of the second terminal, and covers the semiconductor chip.

Exemplary embodiments of a semiconductor device will be explained below in detail with reference to the accompanying drawings. The present invention is not limited to the following embodiments.

### Embodiment

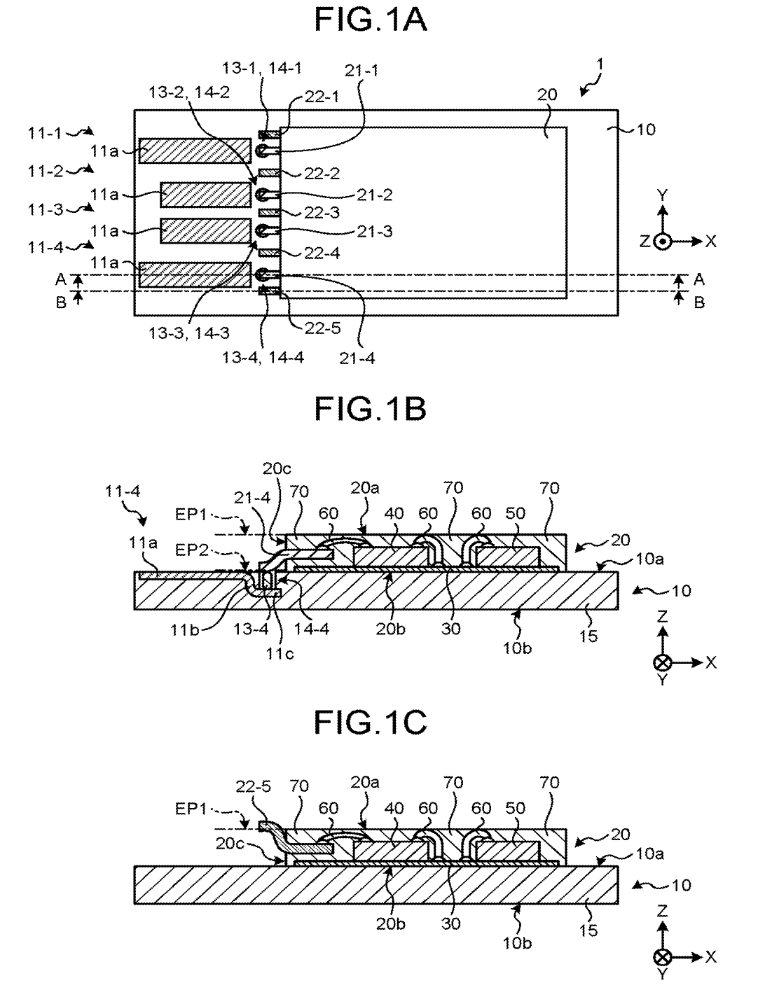

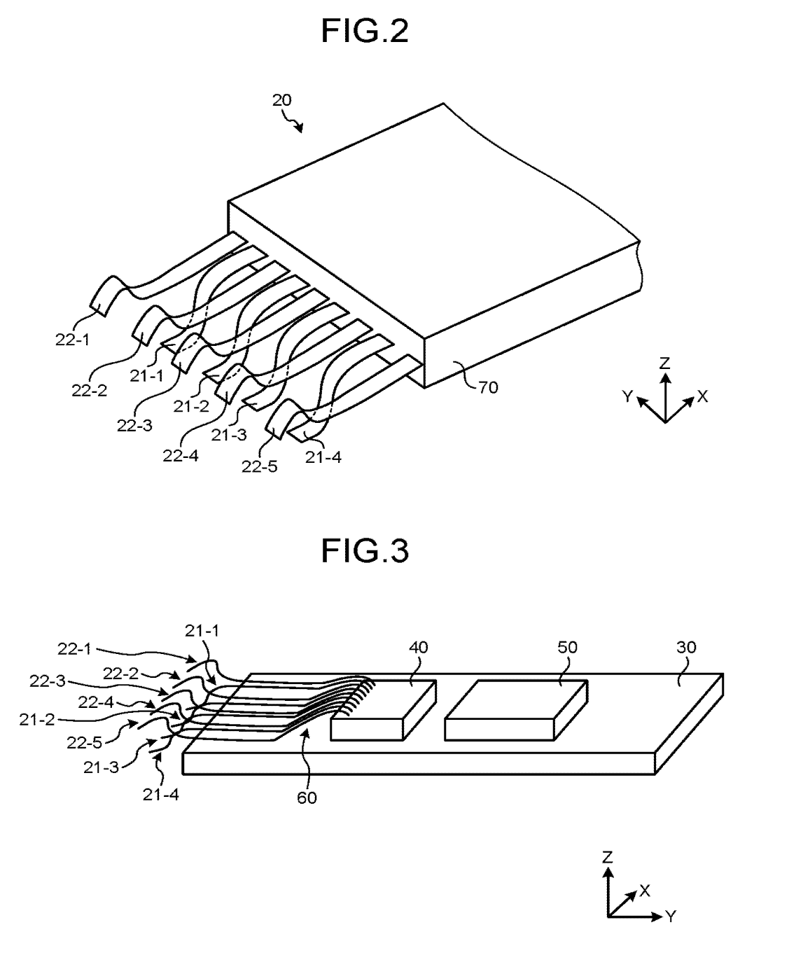

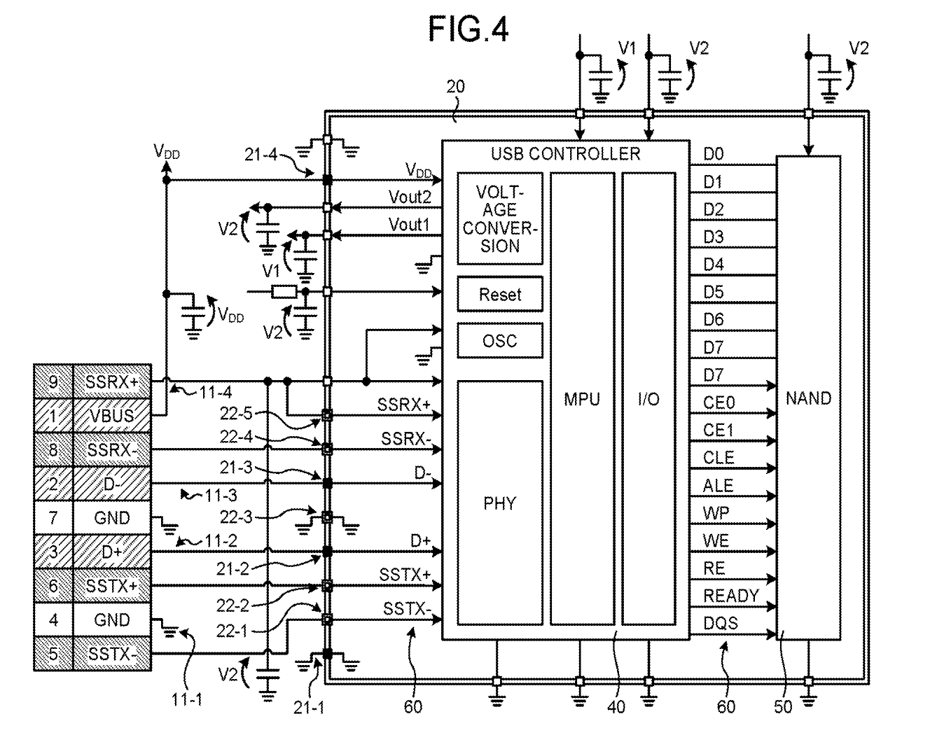

A semiconductor device 1 according to the embodiment will be described with reference to FIGS. 1A to 4. FIG. 1A is a plan view illustrating a configuration of the semiconductor device 1. FIG. 1B is a cross-sectional view taken along line A-A illustrated in FIG. 1A. FIG. 1C is a cross-sectional view taken along line B-B illustrated in FIG. 1A. FIG. 2 is a perspective view illustrating a configuration of a package 20. FIG. 3 is a perspective view illustrating a configuration of the package 20, which is before being sealed by resin. FIG. 4 is a circuit diagram illustrating a configuration of the package 20. In FIGS. 1A to 3, a direction perpendicular to a surface of a substrate 10 or a package substrate 30 is defined as Z direction, and two directions orthogonal to each other in a plane perpendicular to the Z direction are defined as X direction and Y direction.

The semiconductor device 1 has a configuration compatible with, for example, the universal serial bus (USE) standard. For example, sockets compatible with the USE standard are widely mounted on an information processing device such as a personal computer, and various peripheral devices can be connected to the information processing device through the sockets. In the USB standard, for example, four types of specifications, which are USB 1.0, USB 1.1, USB 2.0, and USB 3.0, are defined. The USB 1.1 to the USB 3.0 are backward compatible, and it is required that even when a lower standard device and an upper standard device are connected, the two devices operate correctly except that functions and performances are limited to the lower standard.

As one of the peripheral devices that are connected to an information processing device through a USB socket, there is a so-called USB memory which is a storage device in which a non-volatile flash memory, a controller, and a USB connector (Standard-A) are mounted on the same substrate and housed in a case. Currently, the mainstream of the USB memory is a product compatible with USB 2.0 with a maximum transmission speed of 480 Mbits/s.

The storage capacity of the USB memory is steadily increasing. The amount of data per file handled by an information processing device tends to increase. Therefore, it is required to develop a USE memory compatible with USB 3.0 with a maximum transmission speed of 5 Mbit/s in order to realize higher-speed data transmission between the information processing device and the USB memory.

The backward compatibility is required in the USB standard, so that when a USB memory compatible with the USB 3.0 transmits data either in USB 3.0 or USB 2.0, the USB memory is required to transmit data at a speed specified in each standard. For example, a terminal of USB 2.0 is held on a substrate through a connector for USB 2.0, a hole of a USB 3.0 terminal is opened on the substrate, and the USB 3.0 terminal is held by the substrate through a connector for USB 3.0. A chip is mounted on the substrate in addition to the above, and a housing that covers the connector for USB 2.0, the connector for USB, the substrate, and the chip is put on from the outside. Thereby, a USB memory may be formed. In this case, the number of components of the USB memory (semiconductor device) is large, so that it is difficult to manufacture the USB memory at low cost.

On the other hand, in a System in Package (SiP) technique, a plurality of chips (devices) having various characteristics are formed separately, the chips are separated into individual pieces, and these pieces are mounted on a substrate. In the SiP technique, each device can be individually formed as a chip, so that restrictions of the device are reduced. Further, existing chips can be used when a new system is developed, so that there is an advantage that the development cost is low and the development period is short.

Therefore, in the present embodiment, the number of components of the semiconductor device 1 (USB memory) is reduced and the manufacturing cost reduced by mounting the semiconductor device 1 by using a SiP type package including first terminals compatible with a bus standard of USB 2.0 or above and second terminals compatible with a bus standard of USB 3.0 or above.

Specifically, the semiconductor device 1 includes a substrate 10 and a package 20. The substrate 10 has a planar size greater than that of the package 20. The package 20 is mounted on a surface 10a of the substrate 10. Thereby, the substrate 10 holds the package 20.

As illustrated in FIG. 1A to 1C, the package 20 includes a plurality of first terminals 21-1 to 21-4, a plurality of second terminals 22-1 to 22-5, a package substrate 30, a controller chip (semiconductor chip) 40, a memory chip 50, a metal wires 60, and a resin sealing member 70.

The controller chip 40 and the memory chip 50 are mounted on the package substrate 30. Each of the first terminals to 21-4 is electrically connected to an electrode of the controller chip 40 through a metal wire 60. Each of the second terminals 22-1 to 22-5 is electrically connected to an electrode of the controller chip 40 through a metal wire 60. An electrode of the controller chip 40 and an electrode of the memory chip 50 are electrically connected to each other through metal wires 60 and a wiring (not illustrated in the drawings) in the package substrate 30. In other words, the memory chip 50 is electrically connected to the controller chip 40 on the opposite side of the first terminals 21-1 to 21-4 and the second terminals 22-1 to 22-5.

The resin sealing member 70 covers the plurality of first terminals 21-1 to 21-4, the plurality of second terminals 22-1 to the package substrate 30, the controller chip 40, the memory chip 50, and the metal wires 60 and seals gaps between them. For example, the resin sealing member 70 covers one end of each of the first terminals 21-1 to 21-4 and exposes the other end. The resin sealing member 70 covers one end of each of the second terminals 22-1 to 22-5 and exposes the other end. The resin sealing member 70 covers the package substrate 30, the controller chip 40, the memory chip 50, and the metal wires 60. The resin sealing member 70 contains a mold resin such as, for example, an epoxy resin and a silicone resin.

The plurality of first terminals 21-1 to 21-4 are terminals compatible with a bus standard of USB 2.0 or above. For example, as illustrated in FIG. 4, the first terminal 21-1 corresponds to a GND terminal which is a ground terminal of USB 2.0. The first terminal corresponds to a D+ terminal which is one data terminal of a differential pair of USB 2.0. The first terminal 21-3 corresponds to a D− terminal which is the other data terminal of the differential pair of USD 2.0. The first terminal 21-4 corresponds to a VBUS terminal which is a power supply terminal of USB 2.0.

The plurality of second terminals 22-1 to are terminals compatible with a bus standard of USB above. For example, as illustrated in FIG. 4, the second terminal 22-1 corresponds to an SSTX− terminal which is the other data terminal of a transmission differential pair of USB 3.0. The second terminal 22-2 corresponds to an SSTX+ terminal which is one data terminal of the transmission differential pair of USB 3.0. The second terminal 21-3 corresponds to a GND terminal which is a ground terminal of USB 3.0. The second terminal 22-4 corresponds to an SSRX− terminal which is one data terminal of a reception differential pair of USB 3.0. The second terminal 22-5 corresponds to an SSRX+ terminal which is the other data terminal of the reception differential pair of USB 3.0.

It should be noted that, as illustrated in FIG. 4, the controller chip (USB controller chip) 40 performs an interface operation between the first and the second terminals 21-1 to 21-4 and 22-1 to 22-5 and the memory chip (NAND type flash memory chip) 50.

Each of the first terminals 21-1 to 21-4 and each of the second terminals 22-1 to 22-5 are arranged on a side surface 20c of the package 20 as illustrated in FIGS. 1A to 1C. Each of the first terminals 21-1 to 21-4 and each of the second terminals 22-1 to 22-5 have a substantially rod shape extending in a direction crossing the side surface 20c of the package 20.

Each of the second terminals 22-1 to 22-5 has a shape compatible with a standard of USB connector (Standard-A). For example, as illustrated in FIG. 1B, tip portions of the second terminals 22-1 to 22-5 are closer to an extended surface EP1 of a surface 20a of the package 20 than tip portions f the first terminals 21-1 to 1-4.

The second terminals 22-1 to 22-5 bend and extend from the side surface 20c of the package 20 to positions corresponding to the extended surface EP1 of the surface 20a of the package 20. As illustrated in FIGS. 1C and 2, the second terminals 22-1 to 22-5 extend in −X direction in the package 20. After passing through the side surface 20c of the package 20, the second terminals 22-1 to 22-5 bend and extend in +Z direction while departing from the package 20 in the −X direction. When reaching the extended surface EP1, the second terminals 22-1 to 22-5 extend along the extended surface EP1 while departing from the package 20 in the −X direction.

The first terminals 21-1 to 21-4 bend and extend from the side surface 20c of the package 20 to positions corresponding to an extended surface EP2 of a rear surface 20b of the package 20. As illustrated in FIGS. 1B and 2, the first terminals 21-1 to 1-4 extend in the −X direction in the package 20. After passing through the side surface 20c of the package 20, the first terminals 21-1 to 21-4 bend and extend in −Z direction while departing from the package 20 in the −X direction. When reaching the extended surface EP2, the first terminals 21-1 to 21-4 extend along the extended surface EP2 while departing from the package 20 in the −X direction.

As illustrated in FIGS. 1A. to 1C, the substrate 10 includes a substrate main body 15, a plurality of third terminals 11-1 to 11-4, and ball electrodes 13. A part of each of the third terminals 11-1 to 11-4 is exposed to the surface 10a of the substrate 10 and the other part is buried in the substrate main body 15. In the substrate main body 15, holes 14-1 to 14-4 are formed at positions corresponding to the first terminals 21-1 to 21-4, respectively. The third terminals 11-1 to 11-4 are exposed to bottom surfaces of the holes 14-1 to 14-4, respectively. The ball electrodes 13-1 to 13-4 are arranged in the holes 14-1 to 14-4, respectively, and electrically connected to the third terminals 11-1 to 11-4 exposed to the bottom surfaces of the holes 14-1 to 14-4, respectively. Further, the ball electrodes 13-1 to 13-4 are electrically connected to the first terminals 21-1 to 21-4, respectively. Portions of the ball electrodes 13-1 to 13-4 located at the surface 10a are in contact with the tip portions of the first terminals 21-1 to 21-4, respectively.

The plurality of third terminals 11-1 to 11-4 are terminals compatible with the bus standard of USB 2.0 or above. For example, as illustrated in FIG. 4, the third terminal 11-1 corresponds to a VBUS terminal which is a power supply terminal of USB 2.0. The third terminal 11-2 corresponds to a D− terminal which is one data terminal of a differential pair of USB 2.0. The third terminal 11-3 corresponds to a D+ terminal which is the other data terminal of the differential pair of USB 2.0. The third terminal 11-4 corresponds to a GND terminal which is a ground terminal of USB 2.0.

The third terminals 11-1 to 11-4 are arranged to positions corresponding to the first terminals 21-1 to 21-4, respectively, or the substrate 10 in plan view. For example, the third terminal 11-1 is arranged to a position corresponding to the first terminal 21-1 and is electrically connected to the first terminal 21-1. Third terminal 11-2 is arranged to a position corresponding to the first terminal 21-2 and is electrically connected to the first terminal 21-2. Third terminal 11-3 is arranged to a position corresponding to the first terminal 21-3 and is electrically connected to the first terminal 21-3. Third terminal 11-4 is arranged to a position corresponding to the first terminal 21-4 and is electrically connected to the first terminal 21-4.

Each of the third terminals 11-1 to 11-4 includes a part 11a, a part 11b, and a part 11c. The part 11a is a part of the third terminal 11, which is exposed to the surface 10a of the substrate 10. The part 11a extend along the surface 10a of the substrate 10 and has a substantially rectangular shape in plan view. The part us is a part of the third terminal 11, which is exposed to the bottom surface of the holes 14-1 to 14-4. The part 11c extends along a rear surface 10b of the substrate 10 and has a substantially rectangular shape in plan view. The part 11c is arranged adjacent to the part 11a in the +X direction when seeing through from the Z direction. The part 11b is a part which connects the part 11a and part 11c in the third terminal 11. The part 11b extends in the Z direction and connects an end portion of the part 11a in the +X direction and an end portion of the part 11c in the −X direction.

It should be noted that, although FIG. 1A illustrates a case in which the X direction length of the part 11a of the third terminals 11-2 and 11-3 is smaller than the X direction length of the part 11a of the third terminals 11-1 and 11-4, the X direction length of the part 11a of the third terminals 11-2 and 11-3 may be the same as the X direction length of the part 11a of the third terminal 11-1 and 11-4.

As described above, in the semiconductor device 1 of the embodiment, the package 20 has the first terminals 21-1 to 21-4 compatible with the bus standard of USB 2.0 or above and the second terminals 22-1 to 22-5 compatible with the bus standard of USB 3.0 or above. Further, the package 20 includes the controller chip 40 to which the first terminals 21-1 to 21-4 and the second terminals 22-1 to 22-5 are electrically connected and the memory chip 50 which is electrically connected to the controller chip 40 on the opposite side of the first terminals 21-1 to 21-4 and the second terminals 22-1 to 22-5. Thereby, it is possible to integrally form the semiconductor device 1 (USB memory) as a SiP type package 20 without using a USB connector, so that it is possible to reduce the number of components of the semiconductor device 1 (USB memory) and to reduce the manufacturing cost.

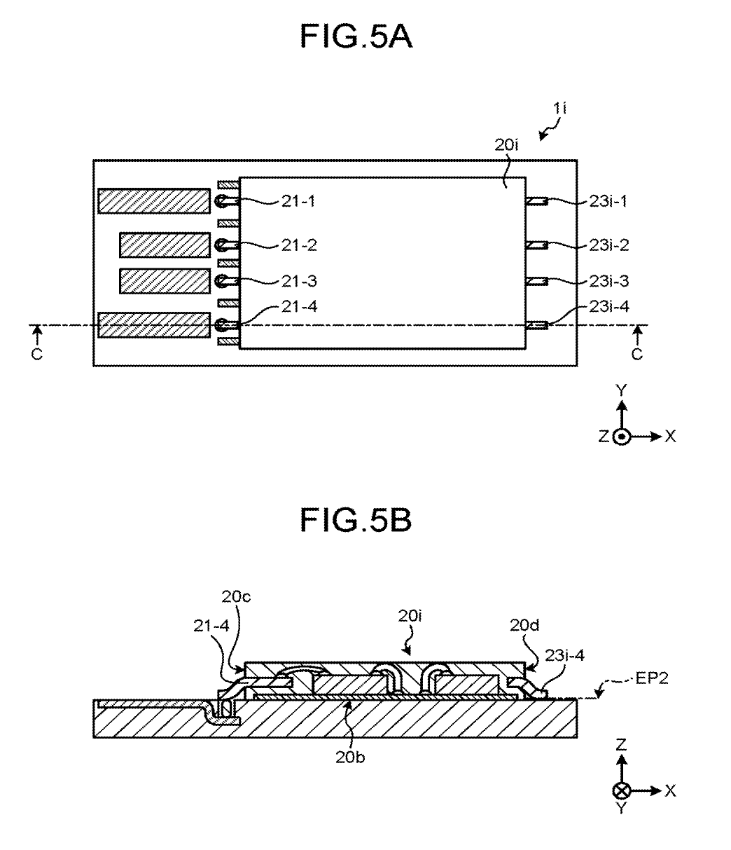

It should be noted that, as illustrated in FIGS. 5A and 5B, in a semiconductor device 1i, a package 20i may further have dummy terminals 23i-1 to 23i-4 which are not electrically connected to the controller chip 40 and the memory chip 50. FIG. 5A is a plan view illustrating a configuration of the semiconductor device 1i. FIG. 5B is a cross-sectional view of the semiconductor device 1i illustrated in FIG. 5A taken along line C-C. The dummy terminals 23i-1 to 23i-4 may be provided on a side of the package 20i opposite to the first terminals 21-1 to 21-4. The dummy terminals 23i-1 to 23i-4 are provided on a side surface 20d of the package 20i opposite to a side surface 20c. As illustrated in FIG. 5A, the dummy terminals 231-1 to 23i-4 are arranged at positions on the side surface 20d corresponding to the first terminals 21-1 to 21-4. The dummy terminals 23i-1 to 23i-4 have shapes corresponding to the first terminals 21-1 to 21-4. The dummy terminals 1 to 23i-4 have a substantially rod shape. The dummy terminals 23i-1 to 23i-4 bend and extend from the side surface 20d of the package 20i to positions corresponding to an extended surface EP2 of a rear surface 20b of the package 20i. As illustrated in FIG. 5B, the dummy terminals 23i-1 to 23i-4 extend in +X direction in the package 20i. After passing through the side surface 20d of the package 201, the dummy terminals 23i-1 to 23i-4 bend and extend in −Z, direction while departing from the package 20i in the +X direction. When reaching the extended surface EP2, the dummy terminals 23i-1 to 23i-4 extend along the extended surface EP2 while departing from the package 20i in the +X direction.

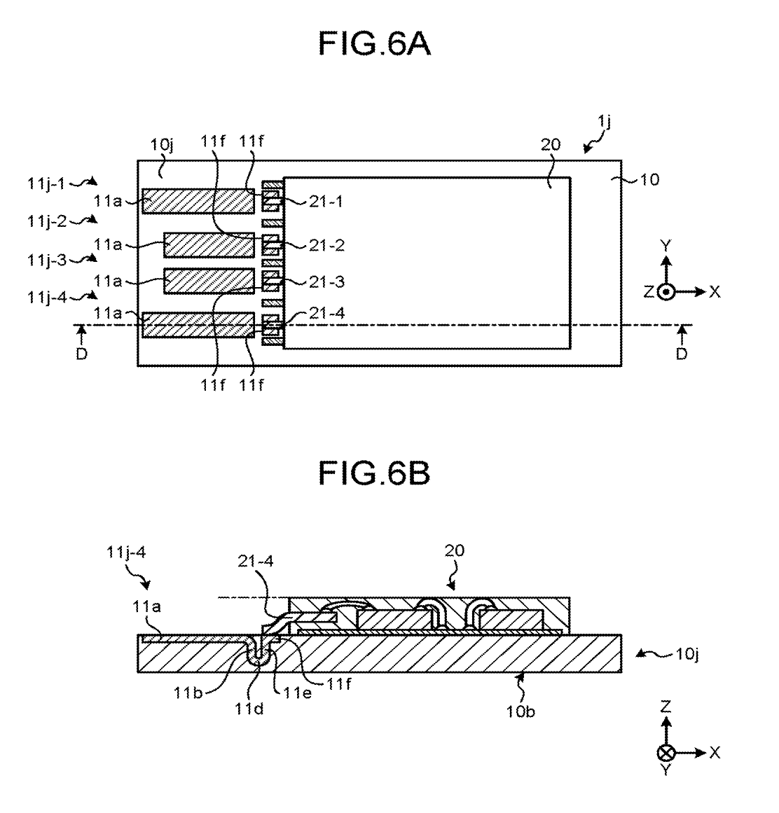

Alternatively, in a semiconductor device 1j, a substrate 104 may have third terminals 11j-1 to 11j-4 as illustrated in FIGS. 6A and 6B instead of the third terminals 11-1 to 11-4 (see FIG. 1A). FIG. 6A is a plan view illustrating a configuration of the semiconductor device 11. FIG. 6B is a cross-sectional view of the semiconductor device 1j illustrated in FIG. 6A taken along line D-D. Each of the third terminals 11j-1 to 11j-4 includes a part lid, a part 11e, and a part 11f instead of the part 11c (see FIG. 1B). The part 11f is a part of the third terminal 11j, which is exposed to the surface 103 of the substrate 10. The part 11a is a part exposed on the substrate 10 in an area farther from the package 20 than the part 11f. The part 1f extends along the surface 10a of the substrate 10 and has a substantially rectangular shape in plan view. The part 11d is a part of the third terminal 11j, which is buried in the substrate 10. The part 11d extends along the rear surface 10b of the substrate 10 and has a substantially rectangular shape in plan view. When seeing through from the Z direction, the part 11d is arranged adjacent to the part 11a in the +X direction and is arranged adjacent to the part 11f in the −X direction. The part 11e is a part which connects the part 11d and part 11f in the third terminal 11j. The part 11e extends in the Z direction and connects an end portion of the part 11d in the +X direction and an end portion of the part 11f in the −X direction. At this time, the first terminals 21-1 to 21-4 are in contact with and electrically connected to the parts 11f of the third terminals 11j-1 to 11j-4, respectively.

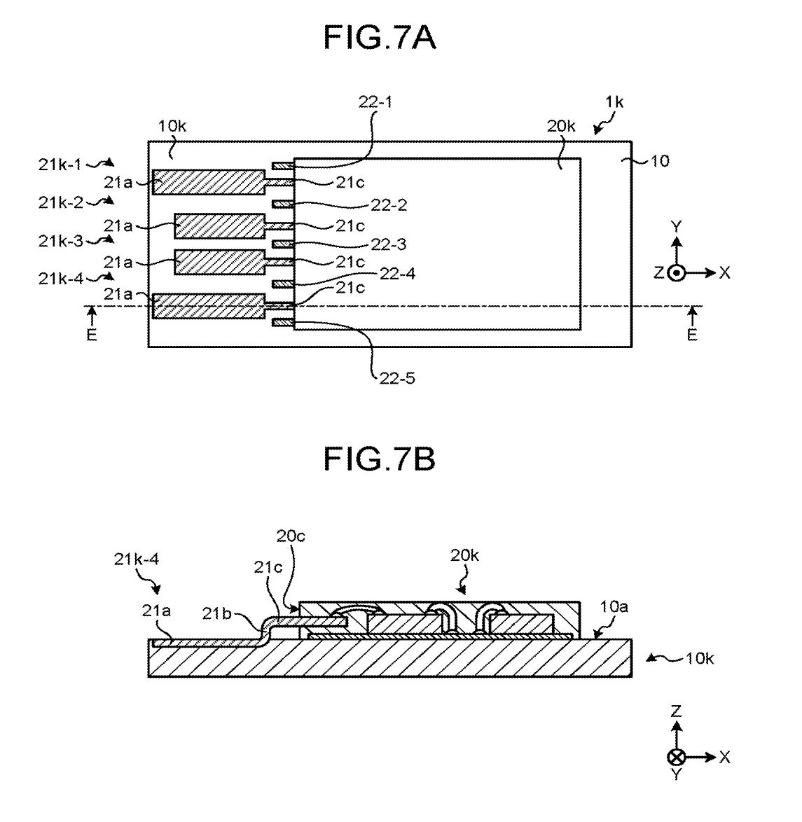

Alternatively, in a semiconductor device 1k, a substrate 10k does not have the plurality of third terminals 11-1 to 11-4, and a package 20k may have first terminals 21k-1 to 21k-4 as illustrated in FIGS. 7A and 7B instead of the first terminals 21-1 to 21-4 (see FIG. 1A). FIG. 7A is a plan view illustrating a configuration of the semiconductor device 1k. FIG. 7B is a cross-sectional view of the semiconductor device 1k illustrated in FIG. 7A taken along line E-E. Each of the first terminals 21k-1 to 21k-4 includes a part 21a, a part 21b, and a part 21c. The width of the part 21a in the Y direction is greater than the widths of the part 21b and the part 21c in the Y direction. The width of the part 21a in the Y direction is greater than the width of each of the second terminal 22-1 to 22-5 in the Y direction. The part 21a is arranged farther from the package 20k than the part 21b and the part 21c. The part 21a has a planar shape corresponding to the part 11a (see FIG. 1A). The part 21a extends along the surface 10a of the substrate 10k and has a substantially rectangular shape in plan view. As illustrated in FIG. 7B, the part 21c extends in the −X direction in the package 20k, and after passing through the side surface 20c of the package 20k, the part 21c continuously extends in the −X direction. The part 21b is a part which connects the part 21a and part 21c in the first terminal 21k. The part 21b extends in the direction and connects an end portion of the part 21a in the +X direction and an end portion of the part 21c in the −X direction.

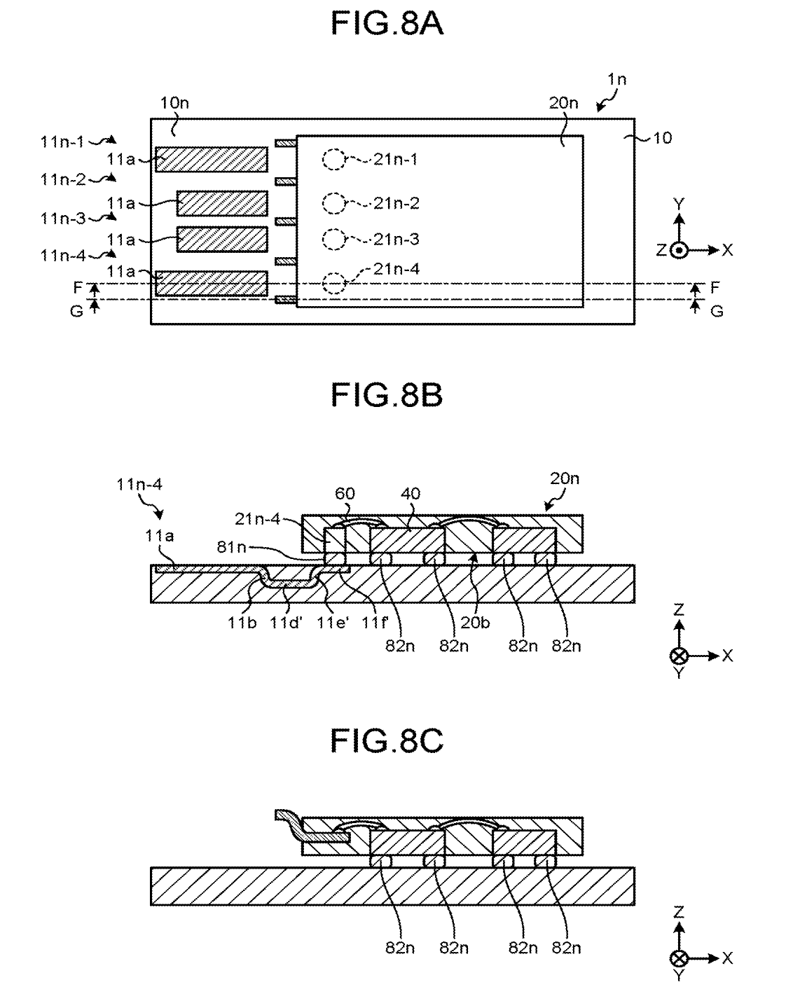

Alternatively, as illustrated in FIGS. 8A to 8C, a semiconductor device in further includes conductor balls 81n and 82n, and the package 20n may have BGA type first terminals 21n-1 to 21n-4 instead of the first terminals 21-1 to 21-4 (see FIG. 1A). A substrate 10n may have third terminals 11n-1 to 11n-4 instead of the third terminals 11-1 to 11-4 (see FIG. 1A). FIG. 8A is a plan view illustrating a configuration of the semiconductor device 1n. FIG. 8B is a cross-sectional view of the semiconductor device in illustrated in FIG. 8A taken along line F-F. FIG. 8C is a cross-sectional view of the semiconductor device in illustrated in FIG. 8A taken along line G-G. The first terminals 21n-1 to 21n-4 are electrically connected to the third electrodes 11n-1 to 11n-4, respectively, through the conductor balls 81n. The conductor balls 81n and 82n are sandwiched be the substrate 10n and the package 20n. The package 20n is held by the substrate 10n through the conductor balls 81n and 82n. The conductor ball 82n is a dummy conductor ball for the package 20n to be stably held by the substrate 10n. As illustrated in FIG. 8B, each of the first terminals 21n-1 to 21n-4 is arranged on the rear surface 20b of the package 20n. Each of the first terminals 21n-1 to 21n-4 has, for example, a substantially cylindrical shape or a substantially square column shape which have a central axis substantially perpendicular to the rear surface 20b of the package 20n. Each of the first terminals 21n-1 to 21n-4 extends in the −Z direction in the package 20n and a portion facing the −Z direction is exposed to the rear surface 20b of the package 20n.

Each of the third terminals 11n-1 to 11n-4 includes a part 11d′, a part 11e′, and a part 11f′ instead of the part 11c (see FIG. 18). The part 11f′ is a part of the third terminal 11n, which is exposed to the surface 10a of the substrate 10n. The part 11a is a part exposed on the substrate 10n in an area farther from the package 20n than the part 11f′. The part 11f′ extends along the surface 10a of the substrate 10n and has a substantially rectangular shape in plan view. The part 11d′ is a part of the third terminal 11n, which is buried in the substrate 10n. The part 11d′ extends along the rear surface 10b of the substrate 10n and has a substantially rectangular shape in plan view. When seeing through from the Z direction, the part 11d′ is arranged adjacent to the part 11a in the +X direction and is arranged adjacent to the part 11f′ in the −X direction. The part 11e′ is a part which connects the part 11d′ and part 11f′ in the third terminal 11n. The part 11e′ extends in the Z direction and connects an end portion of the part in the +X direction and an end portion of the part 11f′ in the −X direction. At this time, the first terminals 21n-1 to 21n-4 are in contact with and electrically connected to the parts 11f′ of the third terminals 11n-1 to 11n-4, respectively, through the conductor balls 81n.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a package including
a first terminal compatible with a first bus standard,
a second terminal compatible with a second bus standard,
a semiconductor chip in which the first terminal and the second terminal are electrically connected, and
a sealing member that covers one end of the first terminal and one end of the second terminal, exposes an other end of the first terminal and an other end of the second terminal, and covers the semiconductor chip.

2. The semiconductor device according to claim 1, wherein
the first bus standard is a standard of USB 2.0 or above, and
the second bus standard is a standard of USB 3.0 or above.

3. The semiconductor device according to claim 1, wherein
the first terminal and the second terminal have a substantially rod shape extending in a direction crossing a side surface of the package.

4. The semiconductor device according to claim 3, wherein
the first terminal and the second terminal are arranged on the side surface of the package, and
a distance between a tip portion of the second terminal and an extended surface of a surface of the package is smaller than a distance between a tip portion of the first terminal and the extended face of the surface of the package.

5. The semiconductor device according to claim 4, wherein
the second terminal bends and extends from the side surface of the package to a position corresponding to the extended surface of the surface of the package, and
the first terminal bends and extends from the side surface of the package to a position corresponding to an extended surface of a rear surface of the package.

6. The semiconductor device according to claim 1, wherein
the first terminal is longer than the second terminal.

7. The semiconductor device according to claim 1, wherein
the first terminal includes
a first part having a first width, and
a second part that is arranged farther from the package than the first part and has a second width greater than the first width.

8. The semiconductor device according to claim 7, wherein
the width of the second part is greater than a width of the second terminal.

9. The semiconductor device according to claim 1, wherein
the first terminal is arranged on a rear surface of the package,
the first terminal has a substantially pillar shape having an axis substantially perpendicular to the rear surface of the package, and
the second terminal has a substantially rod shape extending in a direction crossing a side surface of the package.

10. The semiconductor device according to claim 1, wherein
the first terminal is arranged on a rear surface of the package, and
the second terminal is arranged on a side surface of the package.

11. The semiconductor device according to claim 1, further comprising:
a substrate that includes a third terminal compatible with the first bus standard and holds the package.

12. The semiconductor device according to claim 11, wherein
the third terminal is arranged to a position corresponding to the first terminal on the substrate and is electrically connected to the first terminal.

13. The semiconductor device according to claim 11, wherein
the substrate further includes an electrode that electrically connects the third terminal and the first terminal.

14. The semiconductor device according to claim 11, wherein
the third terminal includes
a first part exposed on the substrate,
a second part that is exposed on the substrate in an area farther from the package than the first part, and
a third part that extends in the substrate to electrically connect the first part and the second part.

15. The semiconductor device according to claim 14, wherein
the first terminal has a substantially rod shape extending in a direction crossing a side surface of the package, bends and extends from the side surface of the package to a position corresponding to an extended surface of a rear surface of the package, and is electrically connected to the first part.

16. The semiconductor device according to claim 15, wherein
the second terminal bends and extends from the side surface of the package to a position corresponding to an extended surface of a surface of the package.

17. The semiconductor device according to claim 14, wherein
the first terminal has a substantially pillar shape having an axis substantially perpendicular to a rear surface of the package and is electrically connected to the first part on a side of the rear surface of the package.

18. The semiconductor device according to claim 17, wherein
the second terminal bends and extends from a side surface of the package to a position corresponding to an extended surface of a surface of the package.

19. The semiconductor device according to claim 1, wherein
the package further includes a dummy terminal that is not electrically connected to the semiconductor chip.

20. The semiconductor device according to claim 1, wherein
the semiconductor chip is a controller chip, and
the package further includes a memory chip that is electrically connected to the controller chip on an opposite side of the first terminal and the second terminal.
